(19) United States
(12) Patent Application Publication
(10) Pub. No.: US 2002/0134684 A1
(43) Pub. Date: Sep. 26, 2002

(54) Seed layer processes

(75) Inventors: Jeffrey M. Calvert, Acton, MA (US); Denis Morrissey, Huntington, NY (US); David Merricks, Coventry (GB)

Correspondence Address: c/o EDWARDS & ANGELL, LLP, Dike, Bronstein, Roberts & Cushman, IP Group, P.O. Box 9169, Boston, MA, 02209, US

(73) Assignee: Shipley Company, L.L.C., Marlborough, MA

(21) Appl. No.: 10/001,683

(22) Filed: Oct. 25, 2001

Related U.S. Application Data
(60) Provisional application No. 60/243,105, filed on Oct. 25, 2000.

(51) Int. Cl. C25D 5/02; H01L 21/288; H01L 21/445

(52) U.S. Cl. 205/118; 205/123

(57) ABSTRACT

Disclosed is a process flows for treating seed layers including copper such that various problems such as oxidation and insufficient coverage can be repaired in an effective and efficient manner.

### BACKGROUND OF THE INVENTION

The present invention relates generally to the field of electroplating. In particular, the present invention relates to the field of copper electroplating on a seed layer.

The trend toward smaller microelectronic devices, such as those with sub-micron geometries, has resulted in devices with multiple metallization layers to handle the higher densities. One common metal used for forming metal lines, also referred to as wiring, on a semiconductor wafer is aluminum. Aluminum has the advantage of being relatively inexpensive, having low resistivity, and being relatively easy to etch. Aluminum has also been used to form interconnections in vias to connect the different metal layers. However, as the size of via/contact holes shrinks to the sub-micron region, a step coverage problem appears which in turn can cause reliability problems when using aluminum to form the interconnections between the different metal layers. Such poor step coverage results in high current density and enhances electromigration.

One approach to providing improved interconnection paths in the vias is to form completely filled plugs by using metals such as tungsten while using aluminum for the metal layers. However, tungsten processes are expensive and complicated, tungsten has high resistivity, and tungsten plugs are susceptible to voids and form poor interfaces with the wiring layers.

Copper has been proposed as a replacement material for interconnect metallizations. Copper has the advantages of improved electrical properties as compared to tungsten and better electromigration property and lower resistivity than aluminum. The drawbacks to copper are that it is more difficult to etch as compared to aluminum and tungsten and it has a tendency to migrate into the dielectric layer, such as silicon dioxide. To prevent such migration, a barrier layer, such as titanium nitride, tantalum nitride and the like, must be used prior to the depositing of a copper layer.

Typical techniques for applying a copper layer, such as electrochemical deposition, are only suitable for applying copper to an electrically conductive layer. Thus, an underlying conductive seed layer, typically a metal seed layer such as copper, is generally applied to the substrate prior to electrochemically depositing copper. Such seed layers may be applied by a variety of methods, such as physical vapor deposition (“PVD”) and chemical vapor deposition (“CVD”). Typically, seed layers are thin in comparison to other metal layers, such as from 50 to 1500 angstroms thick. Such metal seed layers, particularly copper seed layers, may suffer from problems such as metal oxide both on the surface of the seed layer and in the bulk of the layer as well as discontinuities in the layer.

Oxide on a metal seed layer, particularly a copper seed layer, interferes with subsequent copper deposition. Such oxide forms from exposure of the metal seed layer to oxygen, such as air. The longer such seed layer is exposed to oxygen, the greater the amount of oxide formation. Where a copper seed layer is thin, the copper oxide may exist as copper oxide throughout the layer. In other areas of electroplating, such as in electronics finishing, copper oxide layers are typically removed by acidic etching baths. These baths dissolve the oxide layer, leaving a copper metal surface. Such etching processes are not generally applicable to copper seed layers because of the thinness of the seed layer. As the oxide is removed from the seed layer surface there is the danger that the entire seed layer may be removed in places, creating discontinuities in the seed layer.

U.S. Pat. No. 5,824,599 (Shacham-Diamand et al.) discloses a method of preventing oxide formation on the surface of a copper seed layer by conformally blanket depositing under vacuum a catalytic copper layer over a barrier layer on a wafer and then, without breaking the vacuum, depositing a protective aluminum layer over the catalytic copper layer. The wafer is then subjected to an electroless copper deposition solution which removes the protective aluminum layer exposing the underlying catalytic copper layer and then electrolessly deposits copper thereon. However, such method requires the use of a second metal, aluminum, which adds to the cost of the process and the presence of any unremoved protective layer prior to the electroless deposition of the copper may cause problems in the final product, such as an increase in resistivity. In addition, the dissolved aluminum may build up in the electroless copper bath, which could also cause problems in the final product.

Discontinuities or voids are areas in the seed layer where coverage of the metal, such as copper, is incomplete or lacking. Such discontinuities can arise from insufficient blanket deposition of the metal layer, such as depositing the metal in a line of sight fashion. In order for a complete metal layer to be electrochemically deposited on such a seed layer, the discontinuities must be filled in prior to or during the deposition of the final metal layer, or else voids in the final metal layer may occur.

PCT patent application number WO 99/47731 (Chen) discloses a method of providing a seed layer by first vapor depositing an ultra-thin seed layer followed by electrochemically enhancing the ultra-thin seed layer to form a final seed layer. According to this patent application, such a two step process provides a seed layer having reduced discontinuities. The copper seed layer is enhanced by using an alkaline electrolytic bath Acid electrolytic baths for the seed layer enhancement are disclosed to be problematic due to the fact that voids in the seed layer can be created and thus providing poor uniformity in the metal layer deposited thereon. One using this method to enhance a seed layer would have to rinse and neutralize the seed layer before using conventional acidic electrolytic plating baths. In addition, a manufacturer using such alkaline enhancement method in combination with an acid electroplating bath would have to double the number of plating heads on the plating tool or throughput would decrease.

Unfortunately, problems with a seed layer are typically only discovered after a number of subsequent process steps have been performed. At such a point, a significant amount of effort has been expended to produce electronic devices having voids in the final feature filling metal layer. If such seed layer problems are diagnosed earlier in the manufacturing process, they may be repaired, thus reducing the number of defective devices.

Thus, there is a continuing need for methods of repairing seed layers that remove any oxide surface formed, that do not require the use of additional metals, that enhance the lateral growth of seed layers to reduce or remove discontinuities, and that are compatible with commercial metal deposition processes. Further, there is need for diagnosing seed layer defects so that such defects may be repaired prior to subsequent metallization.

### SUMMARY OF THE INVENTION

The present invention describes a process flow for treating seed layers such that various problems such as oxidation and insufficient coverage can be repaired in an effective and efficient manner. Further, the present invention is particularly useful for the diagnosis and repair of defects in copper or copper alloy seed layers, particularly those used in the manufacture of integrated circuits.

In one aspect, the present invention provides a method for electroplating a plurality of electronic devices, each electronic device having apertures and including a copper containing seed layer including the steps of: a) electroplating a layer of metal on the seed layer of a first electronic device to at least substantially fill the apertures; b) testing the first electronic device for voids in the apertures; c) if no voids exist in step b), electroplating a layer of metal on the seed layer of the remaining electronic devices; d) if voids exist in step b), subjecting a second electronic device to a seed layer repair process selected from cathodic activation or lateral growth enhancement, followed by electroplating a layer of metal on the seed layer of the second electronic device to at least substantially fill the apertures; e) testing the second electronic device for voids in the apertures; f) if no voids exist in step e), electroplating a metal layer on the seed layer of the remaining electronic devices following the process of step d); g) if voids exist in step e), subjecting a third electronic device to a seed layer repair process selected from cathodic activation or lateral growth enhancement, followed by electroplating a layer of metal on the seed layer of the third electronic device to at least substantially fill the apertures, provided that the seed layer repair process is different from the seed layer repair process of step d); h) testing the third electronic device for voids in the apertures; i) if no voids exist in step h), electroplating a metal layer on the seed layer of the remaining electronic devices following the process of step g); j) if voids exist in step h), subjecting the remaining electronic devices to a seed layer repair process selected from cathodic activation plus lateral growth enhancement or cathodic activation plus solution seed layer deposition, followed by electroplating a metal layer on the seed layer of the remaining electronic devices.

In a second aspect, the present invention provides a method for electroplating a plurality of electronic devices, each electronic device having apertures and including a copper containing seed layer including the steps of: a) subjecting a first electronic device to a cathodic activation step; b) electroplating a layer of metal on the seed layer of the first electronic device to at least substantially fill the apertures; c) testing the first electronic device for voids in the apertures; d) if no voids exist in step c), subjecting the remaining electronic devices to a cathodic activation step followed by electroplating a layer of metal on the seed layer of the remaining electronic devices; e) if voids exist in step c), subjecting the remaining wafers to a cathodic activation step plus a seed layer repair process selected from lateral growth enhancement or solution seed layer deposition followed by electroplating a layer of metal on the seed layer of the remaining electronic devices.

In a third aspect, the present invention provides a method for manufacturing a plurality of electronic devices, each electronic device having apertures and including a copper containing seed layer, including the steps of: a) electroplating a layer of metal on the seed layer of a first electronic device to at least substantially fill the apertures; b) testing the first electronic device for voids in the apertures; c) if no voids exist in step b), electroplating a layer of metal on the seed layer of the remaining electronic devices; d) if voids exist in step b), subjecting a second electronic device to a seed layer repair process selected from cathodic activation or lateral growth enhancement, followed by electroplating a layer of metal on the seed layer of the second electronic device to at least substantially fill the apertures; e) testing the second electronic device for voids in the apertures; f) if no voids exist in step e), electroplating a metal layer on the seed layer of the remaining electronic devices following the process of step d); g) if voids exist in step e), subjecting a third electronic device to a seed layer repair process selected from cathodic activation or lateral growth enhancement, followed by electroplating a layer of metal on the seed layer of the third electronic device to at least substantially fill the apertures, provided that the seed layer repair process is different from the seed layer repair process of step d); h) testing the third electronic device for voids in the apertures; i) if no voids exist in step h), electroplating a metal layer on the seed layer of the remaining electronic devices following the process of step g); j) if voids exist in step h), subjecting the remaining electronic devices to a seed layer repair process selected from cathodic activation plus lateral growth enhancement or cathodic activation plus solution seed layer deposition, followed by electroplating a metal layer on the seed layer of the remaining electronic devices.

In a fourth aspect, the present invention provides a method for manufacturing a plurality of electronic devices, each electronic device having apertures and including a copper containing seed layer, including the steps of: a) subjecting a first electronic device to a cathodic activation step; b) electroplating a layer of metal on the seed layer of the first electronic device to at least substantially fill the apertures; c) testing the first electronic device for voids in the apertures; d) if no voids exist in step c), subjecting the remaining electronic devices to a cathodic activation step followed by electroplating a layer of metal on the seed layer of the remaining electronic devices; e) if voids exist in step c), subjecting the remaining wafers to a cathodic activation step plus a seed layer repair process selected from lateral growth enhancement or solution seed layer deposition followed by electroplating a layer of metal on the seed layer of the remaining electronic devices.

### BRIEF DESCRIPTION OF THE DRAWINGS

FIG. 1 is a scanning electron micrograph (“SEM”) showing a cross-section of a prior art wafer having copper filled 0.3 μm vias having bottom center voids prepared by a conventional process.

FIG. 2 is a SEM showing a cross-section of a wafer having 0.2 μm vias where the electroplated copper layer contained no voids.

FIG. 3 is a representation of the reduction of an oxidized copper seed layer, not to scale.

FIG. 4 is a representation of a discontinuous seed layer repaired by lateral growth enhancement, not to scale.

FIG. 5 is a representation of solution deposition of a seed layer, not to scale.

FIG. 6 is a process for repairing a copper seed layer according to the invention.

FIG. 7 is an alternate process for repairing a copper seed layer according to the invention.

### DETAILED DESCRIPTION OF THE INVENTION

As used throughout this specification, the following abbreviations shall have the following meanings unless the context clearly indicates otherwise: nm=nanometer; cm=centimeter; μm=micron=micrometer; e-beam=electron beam; mA/cm²=milliamperes per square centimeter; mg/L=milligrams per liter; g/L=grams per liter; ppm=parts per million; and μΩ=micro-Ohm. “Apertures” refer to recessed features, such as trenches and vias. All percentages and ratios are by weight, unless otherwise noted. All numerical ranges are inclusive and combinable.

The present invention provides a process flow by which electronic device substrates, such as integrated circuits, wafers used in the manufacture of semiconductors and integrated circuits, printed wiring boards and the like having seed layers of unknown origin or characteristics can be diagnosed and repaired or modified as necessary to produce void-free deposits of electroplated metal, such as copper or copper alloy, in apertures present in the substrate.

In the manufacture of electronic devices, dielectric layers deposited on silicon wafers, are patterned lithographically to produce apertures such as vias and/or trenches. Typically, such patterning involves (i) coating the dielectric material layer with a positive or negative photoresist, such as those marketed by Shipley Company (Marlborough, Massachusetts); (ii) imagewise exposing, through a mask, the photoresist to radiation, such as light of appropriate wavelength or e-beam; (iii) developing the image in the resist, e.g., with a suitable developer; and (iv) transferring the image through the dielectric layer to the substrate with a suitable transfer technique such as reactive ion etching. Optionally, an antireflective coating is disposed between the photoresist layer and the dielectric matrix material, or alternatively, on the top of the photoresist layer. Such lithographic patterning techniques are well known to those skilled in the art.

Such image transfer or etching creates the apertures in the dielectric material. In general, the minimum width of such apertures used in the manufacture of integrated circuits is approximately 350 nm and below, with typical aspect ratios (height to width) ranging from 1:1 to 10:1, and more typically from 4:1 to 10:1. In general, the width of such features is ≦1 μm, preferably ≦0.5 μm, and more preferably ≦0.18 μm.

For electronic devices using copper or copper alloy as the interconnect metal, the patterned dielectric surface is typically covered with a very thin layer of a barrier material. Suitable barrier materials include metals and metal compounds, such as, but not limited to, tantalum, tantalum nitride, titanium, titanium nitride, tungsten, tungsten nitride, molybdenum, molybdenum nitride, cobalt, cobalt nitride, and the like. These layers are typically applied using physical or chemical vapor deposition techniques. The barrier layer thickness is typically several tens of nanometers, with typical values ranging from about 5 to about 50 nm, and preferably from about 10 to about 20 nm. The function of the barrier layer is prevent copper ions from entering the dielectric layer and subsequently impairing the electrical performance of the electronic device.

On top of the barrier layer, a thin conductive seed layer, such as copper or copper alloy, is typically deposited, such as by physical or chemical vapor deposition techniques. The thickness of the seed layer typically ranges from about 30 to about 300 nm or greater, and preferably from about 50 to about 100 nm. Such seed layer provides a highly conductive coating that allows for subsequent electroplating, i.e. metallization or filling, of the apertures.

In the next step of the manufacture of electronic devices, the barrier and seed-coated wafer is immersed into a copper or copper alloy electroplating solution. These solutions are well known in the art of electroplating for interconnect fabrication. For example, ULTRAFILL™2001 EP copper deposition chemistries, available from Shipley Company (Marlborough, Mass.), may be used for electrolytic copper metallization.

Typical copper electroplating solutions are acidic and contain at least one soluble copper salt and an acidic electrolyte. The electroplating solutions may optionally contain one or more additives, such as halides, accelerators or brighteners, suppressors, levelers, grain refiners, wetting agents, surfactants and the like. A variety of copper salts may be employed in the electroplating solutions, including for example copper sulfates, copper acetates, copper fluoroborate, and cupric nitrates. Copper sulfate pentahydrate is a particularly preferred copper salt. A copper salt may be suitably present in a relatively wide concentration range in the electroplating compositions of the invention. Preferably, a copper salt will be employed at a concentration of from about 1 to about 300 g/L of plating solution, more preferably at a concentration of from about 10 to about 225 g/L, still more preferably at a concentration of from about 25 to about 175 g/L. The copper plating bath may also contain amounts of other alloying elements, such as, but not limited to, tin, zinc, and the like. Thus, the copper electroplating baths may be used to deposit copper or copper alloy.

Suitable acids useful for copper electroplating baths are inorganic or organic. Suitable inorganic acids include, but are not limited to, sulfuric acid, phosphoric acid, nitric acid, hydrogen halide acids, sulfamic acid, fluoroboric acid and the like. Suitable organic acids include, but are not limited to, alkylsulfonic acids such as methanesulfonic acid, aryl sulfonic acids such as phenylsulfonic acid and tolylsulfonic acid, carboxylic acids such as formic acid, acetic acid and propionic acid, halogenated acids such as trifluoromethylsulfonic acid and haloacetic acid, and the like. Particularly suitable organic acids include (C₁-C₁₀)alkylsulfonic acids. Particularly suitable combinations of acids include one or more inorganic acids with one or more organic acids or a mixture of two or more organic acids. The total amount of added acid used in the present electroplating baths may be from about 1 to about 350 g/L, and preferably from 1 to 225 g/L. In certain applications, low acid copper electroplating baths are particularly useful. Such low acid baths typically contain ≦0.4 M electrolyte, and preferably contain 0 g/L of added acid. Such low acid baths are disclosed in European Patent Application EP 952 242 A1 (Landau et al.).

A wide variety of brighteners or accelerators, including known brightener agents, may be employed in copper electroplating compositions invention. Typical brighteners contain one or more sulfur atoms, and typically without any nitrogen atoms and a molecular weight of about 1000 or less. The amount of such accelerators present in the electroplating baths is in the range of from about 0.1 to about 1000 ppm. Preferably, the accelerator compounds are present in an amount of from about 0.5 to about 300 ppm, more preferably from about 1 to about 100 ppm, and still more preferably from about 2 to about 50 ppm. Particularly preferred are copper electroplating baths containing 1.5 mg/L or greater of brightener compounds.

Other suitable organic additives that can be added to the present electroplating baths include one or more suppressors, one or more levelers, one or more surfactants, one or more grain refiners and the like. The amount of such suppressors present in the electroplating baths is in the range of from about 0.1 to about 1000 ppm. Preferably, the suppressor compounds are present in an amount of from about 0.5 to about 500 ppm, and more preferably from about 1 to about 200 ppm. Surfactants are typically added to copper electroplating solutions in concentrations ranging from about 1 to 10,000 ppm based on the weight of the bath, more preferably about 5 to 10,000 ppm. Particularly suitable surfactants for plating compositions of the invention are commercially available polyethylene glycol copolymers, including polyethylene glycol copolymers. Such polymers are available from e.g. BASF (sold by BASF under TETRONIC and PLURONIC tradenames), and copolymers from Chemax. Levelers may optionally be added to the present electroplating baths in amounts of from about 0.01 to about 50 ppm.

With the electronic device, e.g. wafer, in the copper plating solution, a potential waveform is applied between the silicon wafer (as the cathode) and an anode that is typically selected from a metal such as copper, platinum, platinized titania, and iridium oxide. A current is applied and deposition of copper metal occurs from solution onto the seed layer. With appropriate selection of the electroplating formulation chemistry, copper plating occurs initially in the bottom of the apertures and then continues up toward the surface of the wafer until a substantial thickness of copper film is built up outside of the apertures. Such “bottom-up” plating is particularly useful as void formation in the metallized or filled aperture is reduced.

In one embodiment, if a copper bath is used that does not provide bottom-up fill but rather conformal fill, then the copper layer may be reflowed to provide substantilly metal filled apertures. See, for example, European Patent Application No. 1 005 074 (Ding et al.). Such copper reflow method may also be used to reflow a conformally deposited or repaired copper seed layer, such as those repair methods described below.

Chemical mechanical polishing or planarization (“CMP”) is then typically used to remove the excess copper film above the dielectric and provide an extremely planar surface with an inlaid copper deposit in the apertures or recesses. These copper deposits become the conductors in the multi-level circuitry, such as in advanced semiconductor devices. Such CMP techniques are well known to those skilled in the art. In an alternative embodiment, electropolishing may be used to remove the excess copper film above the dielectric and provide an extremely planar surface.

The seed layer including copper, such as copper or copper alloy, serves a critical function in the electrodeposition process and imperfections in the seed layer can adversely impact the ability to produce defect-free inlaid copper-containing deposits. Presently used seed layer deposition processes such as ionized metal plasma or hollow cathode magnetron plasma function by a physical “line of sight” mechanism which typically produces films, typically copper films, that are substantially thicker on the wafer surface (above the apertures) than on either the aperture sidewalls or bottom.

Ideally, the deepest apertures are completely covered with a sufficient thickness of seed layer to effectively carry sufficient current density to initiate uniform electroplating. However, under these conditions the top comers and upper sidewalls of apertures are coated with substantially thicker film (“overhang”) than in the lower regions of the apertures. During subsequent copper or copper alloy electroplating, the copper or copper alloy deposit can grow to confluence from the overhung seed layer before the plating front which has initiated from the bottom of the apertures has reached this point. This closes off the aperture from electroplating reactants and effectively shuts off the electrodeposition process, leaving trapped solution inside the recessed feature resulting in a “top center void” in the copper or copper alloy deposit.

In an alternate embodiment, the copper or copper alloy on the surface of the substrate is thinner, with a less pronounced “overhang” at the top of the apertures, but there is insufficient coverage of the seed layer on the aperture sidewalls or bottom. This condition leads to either slower or no electrodeposition of copper or copper alloy in the lower part of the apertures and fast copper or copper alloy electroplating in the upper regions. Consequently, the upper part of the recessed feature becomes rapidly closed off and creates “bottom voids” in the apertures.

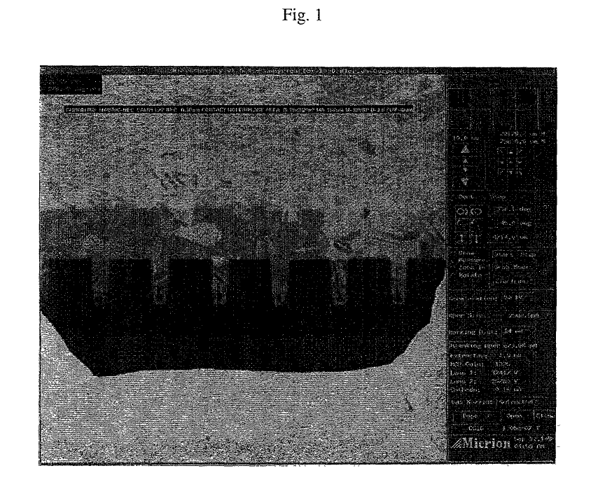

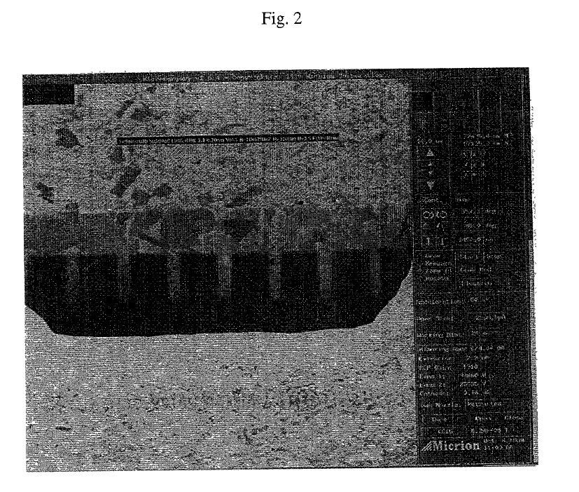

FIG. 1 shows a SEM of a cross-section of a wafer having copper filled 0.3 μm vias having bottom center voids resulting from a conventional process copper electrodeposition process without repairing or modifying the underlying copper seed layer. In contrast, FIG. 2 shows a cross-section of a wafer having 0.2 μm vias where the electroplated copper layer contains no voids. The deposited copper layer shown in FIG. 2 is desired.

The ideal copper containing seed layer is a coating of uniform thickness across the wafer and within the apertures, leaving no areas devoid of the seed layer. The ideal seed layer would be as thin as possible, so as to take up the minimum space within the narrowest recessed features but be of sufficient thickness so as to provide adequate electrical conductivity to support reasonable current densities for the initiation of copper or copper alloy electroplating. Minimum thickness values can range from 50 to 100 nm, and preferably from 10 to 25 nm.

Seed layers suffer from a variety of problems such as discontinuities and oxidation. Discontinuities, or areas devoid of seed layer, are problematic because current does not flow through discontinuities and subsequent electroplating of copper or copper alloy does not occur in these areas, resulting in gaps or voids in the metal deposit.

The oxidation state of the copper in a copper containing seed layer affects the electrodeposition of the subsequently applied copper or copper alloy. Copper metal has a bulk resistivity of 1.67 μΩ-cm. Metallic copper, especially in thin film form, oxidizes very rapidly in the presence of oxygen or air. Oxidized copper, as cupric oxide or cuprous oxide, has a bulk resistivity of higher than that of metallic copper. If a copper seed layer becomes substantially oxidized and the resisitivity of the oxidized regions increases accordingly, the applied current for electroplating will travel preferentially through those unoxidized regions that are of lower resisitivity. Thus, copper electrodeposition will be restricted to those regions through which the current flows, leaving gaps or voids in those regions adjacent to the oxidized seed layer. Given the much higher resistivity of oxidized copper as compared to metallic copper, it can be easily understood that even low percentages (e.g., as little as 10%) may adversely affect the electroplating of copper in the oxidized regions.

In a typical integrated circuit manufacturing process, the barrier and seed layers are first applied to a substrate such as a wafer by vapor deposition techniques. The seed-coated wafers are then removed from the vapor deposition apparatus and are electroplated at some later point in time. The extent of oxidation of the copper seed layer prior to electroplating will depend on a variety of factors such as storage and handling conditions, and also the time interval between seed layer deposition and electroplating. These factors that impact the oxidation state of the seed layer may vary from wafer to wafer, from run to run, from operator to operator, from facility to facility, and so forth.

A number of techniques have been described for improving the quality of copper seed layers in order to produce void-free deposits of electroplated copper or copper alloy in apertures such as vias and trenches. For example, European Patent Application EP 1 005 078 Al (Mikkola et al.) discloses a process for reducing oxidized seed layer to form a recovered seed layer, herein incorporated by reference. In this process, the seed layer containing wafer is placed in an electrolyte bath containing an anode, the wafer being the cathode. The electrolyte bath does not plate metal and thus does not contain copper. The wafer is biased negatively such that a current flows and oxidized components of the seed layer are reduced, forming a deposit composed substantially of zerovalent copper metal. Typically, the bath is operated at a current density in the range of from approximately 0.05 to 500 mA/cm². The wafers are subjected to such electrolyte baths for a time sufficient to substantially reduce the oxidized seed to copper metal. Such time will vary depending upon the current density selected. Typically, this recovery process is continued until hydrogen evolution occurs.

Cathodic activation may also be performed by contacting a seed layer containing oxidized copper disposed on a substrate with an aqueous solution having a pH maintained in the range of about 6.5 to about 13 and subjecting the solution to a voltage of from about 0.1 to 5 volts to reduce the oxidized metal. Such aqueous solution does not contain copper and thus is not a plating solution.

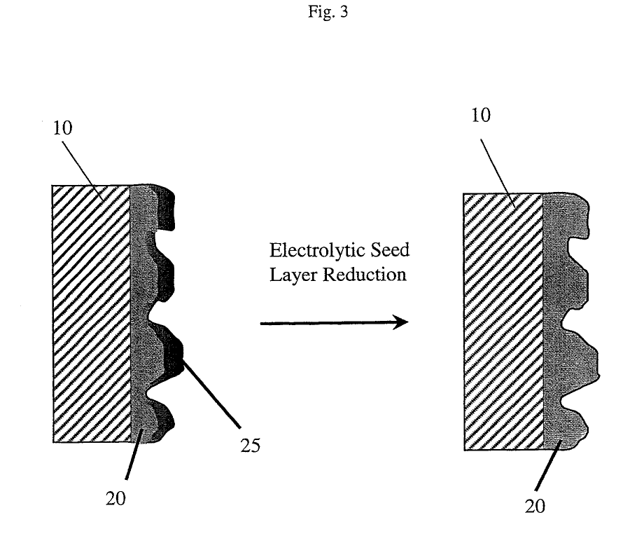

FIG. 3 is a representation of the reduction of an oxidized copper seed layer, not to scale. A copper seed layer 20 is disposed on barrier layer 10. The copper seed layer 20 contains an oxidized portion 25. The oxidized portion 25 is illustrated in FIG. 3 as being surface oxidation, however, such oxidation may also be in the bulk of the seed layer, particularly when the seed layer is thin. Upon reduction, the oxidized portion 25 of the seed layer is substantially reduced to copper to provide copper seed layer 20.

Such electrolytic reduction of the oxidized seed layer, also referred to as cathodic activation, has been shown to provide improved electrolytic deposition of copper in high aspect ratio apertures. Cathodic activation is most useful under conditions where the apertures have sufficient coverage of copper along their entire surface, but where oxidation has proceeded to such an extent that current flow for subsequent copper electrodeposition is impaired or reduced.

Discontinuities in a seed layer may be repaired by laterally enhancing the growth of the copper during an electroplating step such that the copper seed grows across the discontinuities. Such method is also referred to as lateral growth enhancement. For example, see PCT Patent Application WO 99/47731 (Chen), herein incorporated by reference. In this method, a copper seed layer coated wafer is immersed in an alkaline copper containing electrolyte solution, preferably in an alkaline copper bath wherein the copper ions are complexed with a complexing agent such as EDTA, citric acid, ethylene diamine and the like. The pH of this copper bath is preferably at least about 9.

In such lateral growth enhancement method, the wafer is biased negatively such that a current flows and a thin layer of additional copper metal is deposited onto the seed layer. This metal can grow both outward and in a lateral direction from the initial seed layer nuclei. Typically, such seed layer enhancement process continues until a sidewall step coverage, i.e. the ratio of the seed layer thickness at the bottom sidewall regions of the apertures to the nominal thickness of the seed layer at the exteriorly disposed side of the wafer, achieves a value of at least 10%, and preferably at least 20%.

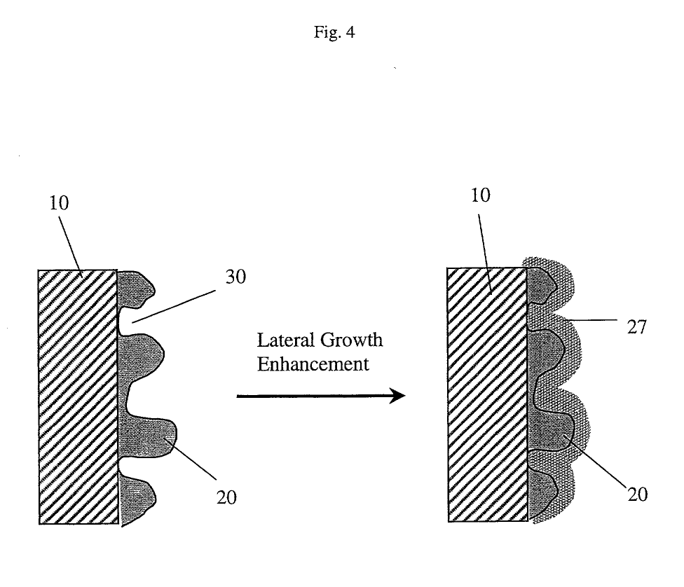

FIG. 4 is a representation of a discontinuous seed layer repaired by lateral growth enhancement, not to scale. A copper seed layer 20 having discontinuities 30 is disposed on barrier layer 10. After being subjected to a lateral growth enhancement process, the discontinuities 30 have been filled in and the copper seed layer 20 contains a laterally enhanced layer 27. Such laterally enhanced layer may be indistinguishable from the originally deposited seed layer.

Such lateral growth enhancement is most useful when the initial seed layer is not too highly oxidized, so that sufficient current can flow in those areas that require the additional copper metal, and also when the coverage of the seed layer is not so low that lateral growth can not bridge the discontinuities in the seed layer.

Discontinuities in seed layers may also be repaired by solution seed layer deposition. In solution seed layer deposition, a plating solution containing copper ions and a reducing agent capable of reducing copper ions to metallic copper is used to deposit a coating of copper. Such solution deposited copper may be deposited on a seed layer having discontinuities or directly onto the barrier layer. When used to deposit copper on a seed layer having discontinuities, the discontinuities are substantially filled to provide a substantially continuous copper seed layer. When such process is used to deposit copper directly on a barrier layer, a substantially continuous copper seed layer is produced. Such copper plating solutions are typically electroless copper plating solutions. Such electroless copper solutions are well known to those skilled in the art.

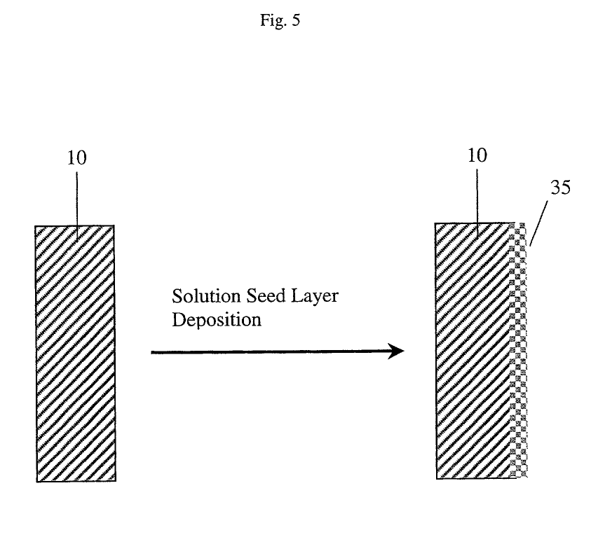

FIG. 5 is a representation of solution deposition of a seed layer, not to scale. A substrate containing barrier layer 10 is contacted with a solution seed layer deposition bath for a period of time sufficient to deposit a copper seed layer 35 layer of the desired thickness on the barrier layer.

While the above described methods are suitable for correcting the various deficiencies of copper seed layers, it is difficult to determine which repair method is needed. In conventional practice, at the time when wafers with copper seed layers are processed by electroplating, both the coverage of the seed layer and the chemical oxidation state of the seed layer may vary from location to location. Although various analytical techniques, such as voltammetry, x-ray photoelectron spectroscopy, focussed ion beam microscopy and scanning electron microscopy, can potentially be used to determine the average coverage and oxidation state of the seed layer on the wafer, it is either not possible or practical to use these methods to determine the local oxidation state and coverage of the copper seed layers in the apertures. It is desirable to have a robust approach for creating copper seed layers having the desired attributes of both high coverage and being substantially free of oxidized copper so as to provide the optimal seed layer surface for copper electroplating.

The principal deficiencies of vapor deposited copper seed layers are that these layers may be either oxidized, contain discontinuities, or both. For example, any of the following situations may apply.

A) Seed layer is metallic, coverage is complete: In this situation, copper electroplating can be performed directly on the seed layer without further optimization.

B) Seed layer is oxidized, but coverage is complete: In this situation, use of the cathodic activation process is required to reduce the oxidized seed layer. The completely covered, metallic seed layer then can initiate uniform electroplating to give void-free copper deposition in the recessed features. Other process techniques are not required to further enhance the seed layer.

C) Seed layer is metallic copper, coverage is substantially uniform but sparse: In this case, the majority of the surface area is covered by the copper seed layer, but in certain areas the coverage is either not completely confluent or is slightly thinner than needed for optimal electroplating, i.e. discontinuities are present. Here, the lateral growth enhancement process can augment the seed layer by deposition of additional metallic copper to fill in sparse areas or provide a slightly greater thickness to the seed layer. Uniform copper electroplating can then be achieved.

D) Seed layer is metallic copper, but coverage is patchy: In these cases, there are substantial regions of the wafer surface, most probably along the sidewalls and at the bottom of high aspect ratio apertures, where the coverage of the seed layer is substantially thinner than that required for proper initiation of electrodeposition, or where the seed layer is absent, i.e. very large discontinuities. Here, neither the cathodic activation or seed layer enhancement processes are likely to be effective but rather a solution seed deposition process is required.

E) Seed layer is oxidized and coverage is either uniform and sparse, or patchy: In these cases, both the cathodic activation process and either lateral growth enhancement or seed deposition from solution need to be used to address the combination of oxidized seed layer and insufficient coverage.

These various scenarios and methods for addressing the deficiencies in the seed layers are summarized in the following Table.

TABLE

| | | Anticipated Result | |
|---|---|---|---|
| Seed Layer | Seed Layer | Without | Modification |
| Coverage | Oxidation State | Modification | Indicated |
| Full | Metallic | Void-free plating | None |
| | | with standard | |
| | | electroplated copper | |
| Full | Oxidized | Failure to initiate | Cathodic activation |
| | | plating in oxidized | |
| | | regions | |
| Uniform, | Metallic | Local voids or | Lateral growth |
| sparse | | defects | enhancement |
| Uniform, | Oxidized | Failure to initiate | Cathodic activation |
| sparse | | plating | plus lateral |
| | | | growth enhancement |
| Patchy | Metallic | Failure to initiate | Lateral growth |
| | | plating in regions | enhancement or |
| | | with insufficient | solution seed |
| | | seed layer coverage | deposition |
| Patchy | Oxidized | Failure to initiate | Cathodic activation |
| | | plating | plus either |
| | | | lateral growth |
| | | | enhancement or |
| | | | solution seed |
| | | | deposition |

Seed layer-coated wafers are obtained in various of the seed layer coverage conditions described in the Table and it is not practical to determine by physicochemical characterization techniques which of the above scenarios are present for a given wafer or lot or wafers. Conventionally, a wafer lot is electroplated and only after all the wafers are plated is an examination of apertures for void formation performed. If voids are found at this stage, the entire lot of wafers may be rejected and the cause of such void formation remains unknown. Thus, in conventional processes there is nothing to prevent such void formation from occurring in the next wafer lot to be plated. Thus, the present invention provides a method for electroplating a plurality of electronic devices, each electronic device having apertures and including a copper containing seed layer including the steps of: a) electroplating a layer of metal on the seed layer of a first electronic device to at least substantially fill the apertures; b) testing the first electronic device for voids in the apertures; c) if no voids exist in step b), electroplating a layer of metal on the seed layer of the remaining electronic devices; d) if voids exist in step b), subjecting a second electronic device to a seed layer repair process selected from cathodic activation or lateral growth enhancement, followed by electroplating a layer of metal on the seed layer of the second electronic device to at least substantially fill the apertures; e) testing the second electronic device for voids in the apertures; f) if no voids exist in step e), electroplating a metal layer on the seed layer of the remaining electronic devices following the process of step d); g) if voids exist in step e), subjecting a third electronic device to a seed layer repair process selected from cathodic activation or lateral growth enhancement, followed by electroplating a layer of metal on the seed layer of the third electronic device to at least substantially fill the apertures, provided that the seed layer repair process is different from the seed layer repair process of step d); h) testing the third electronic device for voids in the apertures; i) if no voids exist in step h), electroplating a metal layer on the seed layer of the remaining electronic devices following the process of step g); j) if voids exist in step h), subjecting the remaining electronic devices to a seed layer repair process selected from cathodic activation plus lateral growth enhancement or cathodic activation plus solution seed layer deposition, followed by electroplating a metal layer on the seed layer of the remaining electronic devices.

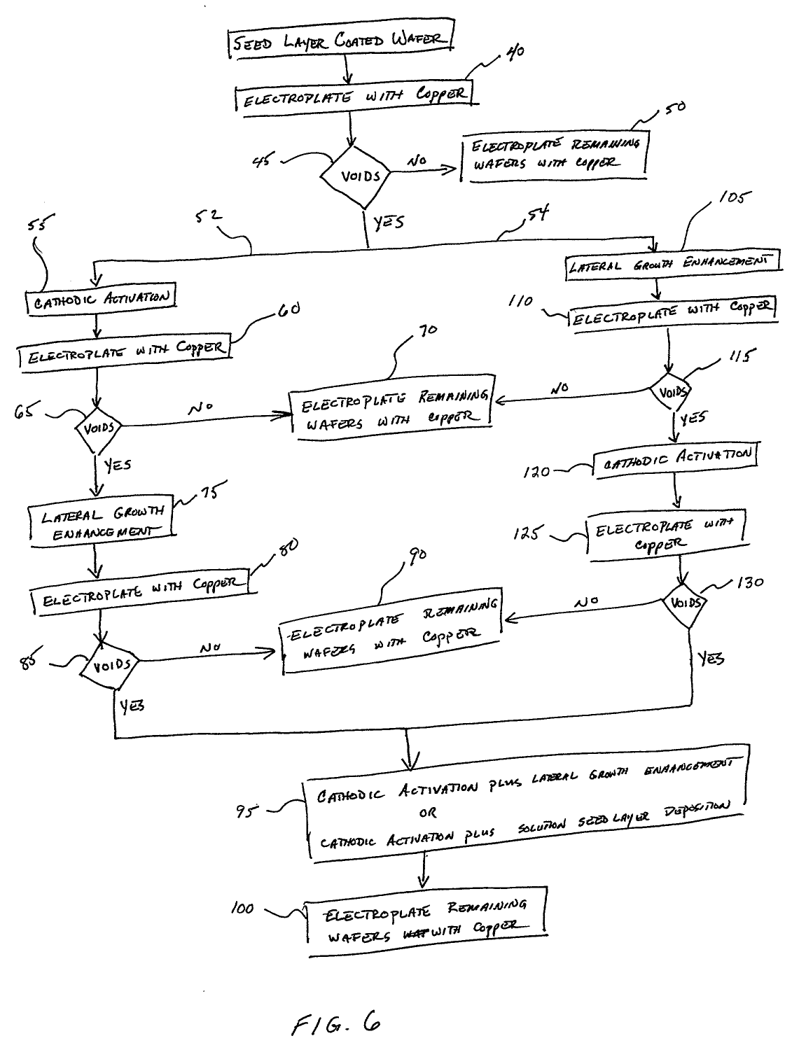

FIG. 6 is a flowchart illustrating an embodiment of the present process for providing an optimal copper or copper alloy seed layer on an electronic device (such as a wafer) or plurality of electronic devices for subsequent electroplating with copper or copper alloy. For purposes of illustration, the process of FIG. 6 will be described with respect to wafers used in the manufacture of integrated circuits. At step 40, copper or copper alloy is electrodeposited on a seed layer of unknown condition disposed on a first wafer from a wafer lot. Such copper or copper alloy is deposited until any apertures are filled or substantially filled. Step 40 is performed using a conventional acidic copper electrolyte with a conventional additive package or low acid (≦0.4 M) and high copper (>0.8 M) electroplating baths such as those disclosed in European Patent Application EP 952 242 A1 (Landau et al.). Conventional acidic copper electroplating baths are well known to those skilled in the art. When, at step 45, the wafer is determined to be free or substantially free of voids in the filled apertures, then no modifications or repair of the seed layer is necessary and the remaining wafers of this lot can be plated with the electroplating bath, at step 50, with a high likelihood of substantially void-free or void-free aperture filling.

When, at step 45, the wafer is determined to have voids in the apertures, then a second wafer from the same wafer lot is subjected to either the use of cathodic activation, at step 55, to reduce any oxidized regions of the copper seed layer to copper metal or subjected to a lateral growth enhancement treatment, at step 105, to augment the coverage of the seed layer. The wafer is then electroplated with copper at step 60 or 110. When, at step 65, the second wafer is determined to be free or substantially free of voids in the filled apertures, then an intermediate cathodic activation step is required prior to copper electroplating and the remaining wafers of this lot are subjected to cathodic activation followed by electroplating with a conventional copper electroplating bath, at step 70, with a high likelihood of substantially void-free or void-free aperture filling. When, at step 115, the second wafer is determined to be free or substantially free of voids in the filled apertures, then an intermediate lateral growth enhancement treatment is required prior to copper electroplating and the remaining wafers of this lot are subjected to lateral growth enhancement followed by electroplating with a conventional copper electroplating bath, at step 70, with a high likelihood of substantially void-free or void-free aperture filling.

When, at step 65, the second wafer is determined to have voids in the apertures, then a third wafer is subjected to lateral growth enhancement at step 75, to augment the coverage of the seed layer and to remediate any minor discontinuities in the seed layer. The wafer is then electroplated with in an acid copper bath at step 80. When, at step 85, the third wafer is determined to be free or substantially free of voids in the filled apertures, then the intermediate step of lateral growth enhancement is required prior to electroplating in an acid copper bath. The remaining wafers of this lot are then subjected to lateral growth enhancement followed by electroplating with a conventional acid copper electroplating bath, at step 90, with a high likelihood of substantially void-free or void-free aperture filling.

When, at step 115, the second wafer is determined to have voids in the apertures, then a third wafer is subjected to cathodic activation at step 120, to reduce any oxidized regions of the copper seed layer to copper metal. The third wafer is then electroplated with in an acid copper bath at step 125. When, at step 130, the wafer is determined to be free or substantially free of voids in the filled apertures, then the intermediate step of cathodic activation is required prior to electroplating in an acid copper bath. The remaining wafers of this lot are then subjected to cathodic activation followed by electroplating with a conventional acid copper electroplating bath, at step 90, with a high likelihood of substantially void-free or void-free aperture filling.

When, at steps 85 or 130, the third wafer is determined to have voids in the apertures, then both oxidation and discontinuities are present in the seed layer. The remaining wafers are then subjected to a combination of both cathodic activation and either lateral growth enhancement or solution seed layer deposition at step 95 followed by electroplating in a conventional acid copper bath, at step 100, with a high likelihood of substantially void-free or void-free aperture filling.

In an alternate embodiment, the present invention provides a method for electroplating a plurality of electronic devices, each electronic device having apertures and including a copper containing seed layer including the steps of: a) subjecting a first electronic device to a cathodic activation step; b) electroplating a layer of metal on the seed layer of the first electronic device to at least substantially fill the apertures; c) testing the first electronic device for voids in the apertures; d) if no voids exist in step c), subjecting the remaining electronic devices to a cathodic activation step followed by electroplating a layer of metal on the seed layer of the remaining electronic devices; e) if voids exist in step c), subjecting the remaining wafers to a cathodic activation step plus a seed layer repair process selected from lateral growth enhancement or solution seed layer deposition followed by electroplating a layer of metal on the seed layer of the remaining electronic devices.

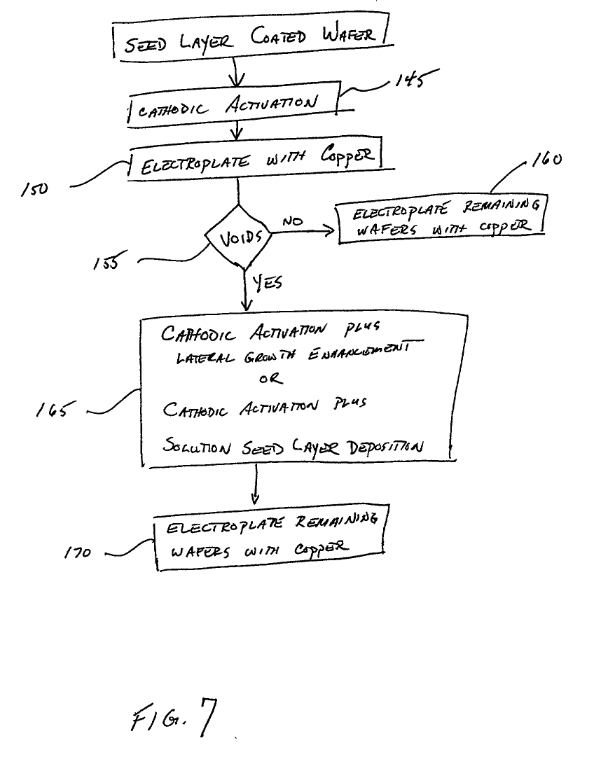

FIG. 7 is a flowchart illustrating an alternate embodiment of the present process. For purposes of illustration, the process of FIG. 7 will be described with respect to wafers used in the manufacture of integrated circuits. At step 145, a first wafer containing a seed layer of unknown condition is subjected to a cathodic activation treatment followed at step 150 by electrodepositing a copper or copper alloy. Such copper or copper alloy is deposited until any apertures are filled or substantially filled. Step 150 is performed using a conventional acidic copper electrolyte with a conventional additive package or a low acid (≦0.4 M) and high copper (>0.8 M) electroplating bath. When, at step 155, the wafer is determined to be free or substantially free of voids in the filled apertures, then the remaining wafers of this lot are subjected to cathodic activation followed by electroplating in an acid copper bath at step 160, with a high likelihood of substantially void-free or void-free aperture filling. When, at step 155, the wafer is determined to have voids in the apertures, then both oxidation and discontinuities are present in the seed layer. The remaining wafers are then subjected to a combination of both cathodic activation and either lateral growth enhancement or solution seed layer deposition at step 165 followed by electroplating in a conventional acid copper bath, at step 170, with a high likelihood of substantially void-free or void-free aperture filling.

It is not always necessary to have an oxide removal step in the seed layer repair process. For example, when the seed layers are freshly deposited on the substrate and are electroplated within a short period of time (days), the oxide build-up in the seed layer coating will be minimal. Contact with the acid copper electroplating solution will sufficiently remove the little oxide that had formed. Performing a cathodic activation step in this case adds to the cost of the manufacturing process without being necessary.

In other cases where copper seed layer coated substrates have been stored for a period of time (weeks) a significant oxide build-up is likely to have occurred in the seed layer. Contact with the acid copper electroplating solution will remove a significant portion of the oxidized seed layer, likely producing discontinuities in the process. Thus, for substrates containing such older seed layers, it is preferable to subject the seed layers on such substrates to a cathodic activation step prior to any acid copper electroplating step. In such cases, the process illustrated in FIG. 7 is preferred.

In an alternate embodiment, a representative wafer from a wafer lot is examined to determine the existence and amount of any copper oxide in the seed layer. Such examination may be by a variety of means, including monitoring of the metal oxide reduction. Such monitoring may be performed by a variety of means, such as by use of a QC-100™ Surface Scan instrument (available from ECI, New Jersey) or any suitable potentiostat. Typically, monitoring is achieved by using a potentiostat equipped with a three electrode system, which maintains a small cathodic current on the seed layer containing substrate. The potentiostat monitors the potential between the substrate and the reference electrode. Alternatively, a constant potential can be applied to the substrate and the resulting current measured. A small current is passed at a reasonable voltage. As the various metal oxide species are reduced, the most easily reduced to the most difficult to reduce, the potential first rises to the characteristic reduction potential for that specific metal oxide, then remains constant while that species is completely converted to metal. The potential then rises to the next characteristic potential and continues until all reducible species are converted to metal. This method ensures that all metal oxide species are reduced to their metallic state, maximizing the conductivity of the seed layer. Such method may be performed in a standard electrolytic plating cell after installing an insoluble anode as well as replacing a rectifier with an appropriate potentiostat. In this way, the presence of copper oxide can be determined. If copper oxide is found, then the remaining wafers in the particular lot are subjected to cathodic activation and the process illustrated in FIG. 7 is followed. If copper oxide is not found by such monitoring, then the wafers are electroplated with copper and the process illustrated FIG. 6 is followed, except that the cathodic activation sequence need not be performed.

The present invention also provides a process flow for optimizing vapor deposited copper or copper alloy seed layers that overcomes the limitations of conventional techniques. This flow is a decision tree that uses various seed layer techniques in appropriate sequences or combinations in order to most efficiently and effectively produce a substantially metallic seed layer without substantial deficiency in copper seed coverage from seed layer coated wafers.

The present invention further provides a method for manufacturing a plurality of electronic devices, each electronic device having apertures and including a copper containing seed layer, including the steps of: a) electroplating a layer of metal on the seed layer of a first electronic device to at least substantially fill the apertures; b) testing the first electronic device for voids in the apertures; c) if no voids exist in step b), electroplating a layer of metal on the seed layer of the remaining electronic devices; d) if voids exist in step b), subjecting a second electronic device to a seed layer repair process selected from cathodic activation or lateral growth enhancement, followed by electroplating a layer of metal on the seed layer of the second electronic device to at least substantially fill the apertures; e) testing the second electronic device for voids in the apertures; f) if no voids exist in step e), electroplating a metal layer on the seed layer of the remaining electronic devices following the process of step d); g) if voids exist in step e), subjecting a third electronic device to a seed layer repair process selected from cathodic activation or lateral growth enhancement, followed by electroplating a layer of metal on the seed layer of the third electronic device to at least substantially fill the apertures, provided that the seed layer repair process is different from the seed layer repair process of step d); h) testing the third electronic device for voids in the apertures; i) if no voids exist in step h), electroplating a metal layer on the seed layer of the remaining electronic devices following the process of step g); j) if voids exist in step h), subjecting the remaining electronic devices to a seed layer repair process selected from cathodic activation plus lateral growth enhancement or cathodic activation plus solution seed layer deposition, followed by electroplating a metal layer on the seed layer of the remaining electronic devices.

In an alternate embodiment, the present invention also provides a method for manufacturing a plurality of electronic devices, each electronic device having apertures and including a copper containing seed layer, including the steps of: a) subjecting a first electronic device to a cathodic activation step; b) electroplating a layer of metal on the seed layer of the first electronic device to at least substantially fill the apertures; c) testing the first electronic device for voids in the apertures; d) if no voids exist in step c), subjecting the remaining electronic devices to a cathodic activation step followed by electroplating a layer of metal on the seed layer of the remaining electronic devices; e) if voids exist in step c), subjecting the remaining wafers to a cathodic activation step plus a seed layer repair process selected from lateral growth enhancement or solution seed layer deposition followed by electroplating a layer of metal on the seed layer of the remaining electronic devices.

What is claimed is:

1. A method for electroplating a plurality of electronic devices, each electronic device having apertures and comprising a copper containing seed layer comprising, comprising the steps of:
a) electroplating a layer of metal on the seed layer of a first electronic device to at least substantially fill the apertures;
b) testing the first electronic device for voids in the apertures;
c) if no voids exist in step b), electroplating a layer of metal on the seed layer of the remaining electronic devices;
d) if voids exist in step b), subjecting a second electronic device to a seed layer repair process selected from cathodic activation or lateral growth enhancement, followed by electroplating a layer of metal on the seed layer of the second electronic device to at least substantially fill the apertures;
e) testing the second electronic device for voids in the apertures;
f) if no voids exist in step e), electroplating a metal layer on the seed layer of the remaining electronic devices following the process of step d);
g) if voids exist in step e), subjecting a third electronic device to a seed layer repair process selected from cathodic activation or lateral growth enhancement, followed by electroplating a layer of metal on the seed layer of the third electronic device to at least substantially fill the apertures, provided that the seed layer repair process is different from the seed layer repair process of step d);
h) testing the third electronic device for voids in the apertures;
i) if no voids exist in step h), electroplating a metal layer on the seed layer of the remaining electronic devices following the process of step g);
j) if voids exist in step h), subjecting the remaining electronic devices to a seed layer repair process selected from cathodic activation plus lateral growth enhancement or cathodic activation plus solution seed layer deposition, followed by electroplating a metal layer on the seed layer of the remaining electronic devices.

2. The method of claim 1 wherein the seed layer is a copper alloy.

3. The method of claim 1 wherein the plurality of electronic devices is a plurality of wafers.

4. The method of claim 1 wherein each of the electronic devices further comprises a barrier layer.

5. The method of claim 4 wherein the barrier layer is selected from tantalum, tantalum nitride, titanium, titanium nitride, tungsten, tungsten nitride, molybdenum, molybdenum nitride, cobalt, cobalt nitride.

6. The method of claim 1 wherein the apertures have a width ≦1 μm.

7. The method of claim 1 wherein the apertures have an aspect ratio of from 1:1 to 10:1.

8. A method for electroplating a plurality of electronic devices, each electronic device having apertures and comprising a copper containing seed layer comprising the steps of:
a) subjecting a first electronic device to a cathodic activation step;
b) electroplating a layer of metal on the seed layer of the first electronic device to at least substantially fill the apertures;
c) testing the first electronic device for voids in the apertures;
d) if no voids exist in step c), subjecting the remaining electronic devices to a cathodic activation step followed by electroplating a layer of metal on the seed layer of the remaining electronic devices;
e) if voids exist in step c), subjecting the remaining wafers to a cathodic activation step plus a seed layer repair process selected from lateral growth enhancement or solution seed layer deposition followed by electroplating a layer of metal on the seed layer of the remaining electronic devices.

9. The method of claim 8 wherein the plurality of electronic devices is a plurality of wafers.

10. The method of claim 8 wherein each of the electronic devices further comprises a barrier layer.

11. The method of claim 10 wherein the barrier layer is selected from tantalum, tantalum nitride, titanium, titanium nitride, tungsten, tungsten nitride, molybdenum, molybdenum nitride, cobalt, cobalt nitride.

12. the method of claim 8 wherein the apertures have a width ≦1 μm.

13. The method of claim 8 wherein the apertures have an aspect ratio of from 1:1 to 10:1.

14. A method for manufacturing a plurality of electronic devices, each electronic device having apertures and comprising a copper containing seed layer, comprising the steps of:
a) electroplating a layer of metal on the seed layer of a first electronic device to at least substantially fill the apertures;
b) testing the first electronic device for voids in the apertures;
c) if no voids exist in step b), electroplating a layer of metal on the seed layer of the remaining electronic devices;
d) if voids exist in step b), subjecting a second electronic device to a seed layer repair process selected from cathodic activation or lateral growth enhancement, followed by electroplating a layer of metal on the seed layer of the second electronic device to at least substantially fill the apertures;
e) testing the second electronic device for voids in the apertures;
f) if no voids exist in step e), electroplating a metal layer on the seed layer of the remaining electronic devices following the process of step d);
g) if voids exist in step e), subjecting a third electronic device to a seed layer repair process selected from cathodic activation or lateral growth enhancement, followed by electroplating a layer of metal on the seed layer of the third electronic device to at least substantially fill the apertures, provided that the seed layer repair process is different from the seed layer repair process of step d);
h) testing the third electronic device for voids in the apertures;
i) if no voids exist in step g), electroplating a metal layer on the seed layer of the remaining electronic devices following the process of step g);
j) if voids exist in step g), subjecting the remaining electronic devices to a seed layer repair process selected from cathodic activation plus lateral growth enhancement or cathodic activation plus solution seed layer deposition, followed by electroplating a metal layer on the seed layer of the remaining electronic devices.

15. The method of claim 14 wherein the plurality of electronic devices is a plurality of wafers.

16. The method of claim 14 wherein each of the electronic devices further comprises a barrier layer.

17. The method of claim 14 wherein the apertures have a width ≦1 μm.

18. The method of claim 14 wherein the apertures have an aspect ratio of from 1:1 to 10:1.

19. A method for manufacturing a plurality of electronic devices, each electronic device having apertures and comprising a copper containing seed layer, comprising the steps of:
a) subjecting a first electronic device to a cathodic activation step;
b) electroplating a layer of metal on the seed layer of the first electronic device to at least substantially fill the apertures;
c) testing the first electronic device for voids in the apertures;
d) if no voids exist in step c), subjecting the remaining electronic devices to a cathodic activation step followed by electroplating a layer of metal on the seed layer of the remaining electronic devices;
e) if voids exist in step c), subjecting the remaining wafers to a cathodic activation step plus a seed layer repair process selected from lateral growth enhancement or solution seed layer deposition followed by electroplating a layer of metal on the seed layer of the remaining electronic devices.
